(19) United States
(12) Patent Application Publication
(10) Pub. No.: US 2025/0136383 A1
(43) Pub. Date: May 1, 2025

(54) TRANSPORT APPARATUS

(71) Applicant: SEMES CO., LTD., Chungcheongnam-do (KR)

(72) Inventors: Hyun Jun LEE, Gyeonggi-do (KR); Tae Hyun JO, Gyeonggi-do (KR)

(21) Appl. No.: 18/885,692

(22) Filed: Sep. 15, 2024

(30) Foreign Application Priority Data
Oct. 26, 2023 (KR) 10-2023-0144820

(51) Int. Cl. B65G 35/06; B66C 11/08

(52) U.S. Cl. CPC B65G 35/06; B66C 11/08; B65G 2203/0233; B65G 2203/044

(57) ABSTRACT

A transport apparatus includes: a vehicle; a housing connected to the vehicle and forming an internal space with an open bottom; a hand unit provided to be movable in an up-down direction, in the housing, and to grip and upgrip a transport object; and a slide unit separated from the hand unit, in the housing, and moving horizontally in a direction where the hand unit is disposed, wherein the slide unit includes: a base plate provided in the internal space of the housing; a slide plate sliding from the base plate in the direction where the hand unit is disposed and seating the transport object; and a drive module provided on the base plate, and sliding the slide plate so that the slide plate protrudes from the base plate.

### CROSS-REFERENCE TO RELATED APPLICATION

This application claims priority from Korean Patent Application No. 10-2023-0144820 filed on Oct. 26, 2023 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a transport apparatus.

### 2. Description of the Related Art

A semiconductor device manufacturing process can be continuously performed within semiconductor manufacturing equipment and can be divided into front-end and back-end processes. The semiconductor manufacturing equipment can be installed in a space defined as a FAB to manufacture semiconductor devices.

The front-end process refers to forming circuit patterns on a substrate (e.g., a wafer) to complete a chip. The front-end process may include a deposition process for forming thin films on the substrate, a photolithography process for transferring photoresist onto the thin films using photomasks, an etching process for selectively removing unnecessary parts using chemicals or reactive gases to form desired circuit patterns on the substrate, an ashing process for removing the remaining photoresist after etching, an ion implantation process for injecting ions into parts connected to the circuit patterns to impart the characteristics of electronic devices, and a cleaning process for removing contaminants from the substrate.

The back-end process refers to evaluating the performance of the products completed through the front-end process. The back-end process may include a substrate inspection process for inspecting chips on the substrate for operation to sort good products from defective ones, a package process for cutting and separating the chips to form the shape of the products through dicing, die bonding, wire bonding, molding, marking, etc., and a final inspection process for ultimately inspecting the characteristics and reliability of the products through electrical characteristic inspection, burn-in inspection, etc.

### SUMMARY

Aspects of the present disclosure provide a transport apparatus capable of simultaneously transporting multiple magazines using an Overhead Hoist Transport (OHT).

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a transport apparatus includes: a vehicle; a housing connected to the vehicle and forming an internal space with an open bottom; a hand unit provided to be movable in an up-down direction, in the housing, and to grip and upgrip a transport object; and a slide unit separated from the hand unit, in the housing, and moving horizontally in a direction where the hand unit is disposed, wherein the slide unit includes: a base plate provided in the internal space of the housing; a slide plate sliding from the base plate in the direction where the hand unit is disposed and seating the transport object; and a drive module provided on the base plate, and sliding the slide plate so that the slide plate protrudes from the base plate.

According to another aspect of the present disclosure, a transport apparatus includes: a vehicle; a housing connected to the vehicle and forming an internal space with an open bottom; a hand unit provided to be movable in an up-down direction, in the housing, and to grip and release a transport object, which is provided as a magazine housing chips; a lifting unit including a belt with adjustable length to raise and lower the hand unit, in the housing; and a pair of slide units provided facing each other with the hand unit therebetween within the internal space of the housing, and moving horizontally in a direction where the hand unit is disposed, wherein the slide unit includes: a base plate provided in the internal space of the housing, formed with a first cutting hole into which one side of the transport object is inserted, and provided with a first transport object detachment prevention unit forming a band shape surrounding the transport object; a slide plate including a first plate covering the lower part of the first cutting hole and seating the transport object, and a second plate provided between the base plate and the first plate, formed with a second cutting hole corresponding to the first cutting hole, and sliding from the base plate in the direction where the hand unit is disposed; a drive module including a moving block fixed to the slide plate, a ball screw penetrated by the moving block, and a first motor provided on the base plate to rotate the ball screw, and causing the slide plate to slide and protrude from the base plate as the moving block moves due to the rotation of the ball screw driven by the first motor; a reflector provided at a position where the transport object is seated on an upper surface of the slide plate; a first sensor provided at the first transport object detachment prevention unit to detect the reflector; a contact sensor provided on the slide plate to detect the transport object; a first detachment prevention block provided on the upper surface of the slide plate, contacting one side of the transport object, and formed with an inclined surface that guides a path where the transport object is seated from top to bottom; a second detachment prevention block provided on the upper surface of the slide plate, opposite to the first detachment prevention block, and contacting the other side of the transport object; and a pair of fall prevention parts provided on both sides of the transport object on the first plate, each of the fall prevention parts includes: an upper roller having a length in the longitudinal direction of the transport object; a lower roller provided below the upper roller; and a rotating body allowing the upper roller and the lower roller to rotate, provided to pivot on the slide plate and having a “V” shape that rotates to allow the upper roller to contact the transport object when the transport object contacts the lower roller, and the hand unit further includes: a chucking module gripping the transport object, including a gripper that slides to fit onto or separate from the top of the magazine and a chip detachment prevention bar extending across the front and rear of the magazine to prevent the chips housed in the magazine from being detached; and a rotation module including a fixed body to which the belt is fixed, a turntable rotating relative to the fixed body with a rotation angle ranging from 0° to 270°, and a second motor provided on the fixed body to rotate the turntable.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 illustrates a transport apparatus according to some embodiments of the present disclosure;

FIG. 2 illustrates a hand unit and a slide unit of the transport apparatus according to some embodiments of the present disclosure;

FIG. 3 is a perspective view of a hand unit and a slide unit of a transport apparatus according to a first embodiment of the present disclosure, and

FIG. 4 is a perspective view of the slide unit of the transport apparatus according to the first embodiment of the present disclosure.

### DETAILED DESCRIPTION

The following detailed description provides preferred embodiments of the present disclosure with reference to the accompanying drawings. The advantages and features of the present disclosure, as well as the methods of achieving them, will become apparent by referring to the detailed embodiments described below in conjunction with the drawings. However, the present disclosure is not limited to the embodiments disclosed herein and can be implemented in various forms. The provided embodiments are intended to fully disclose the invention and to convey the complete scope of the invention to those skilled in the art. The invention is defined only by the scope of the claims. Throughout the specification, like reference numerals refer to like elements.

The terminology used in this specification is intended to describe embodiments and is not intended to limit the invention. In this specification, the singular includes the plural unless otherwise specifically stated. The terms “comprises” and/or “comprising,” as used herein, do not exclude the presence or addition of one or more other elements, steps, operations, and/or features.

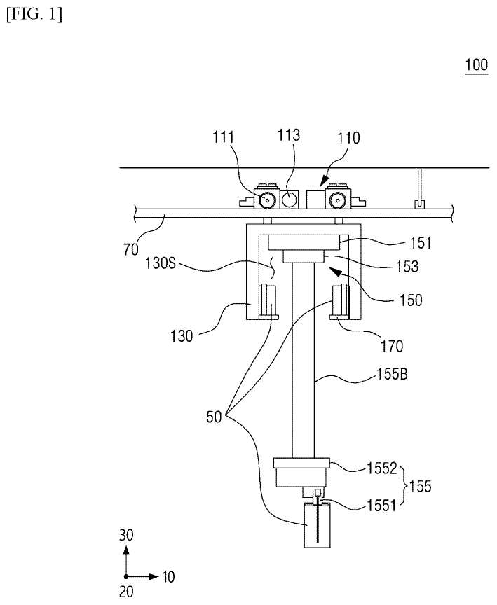

FIG. 1 illustrates a transport apparatus according to some embodiments of the present disclosure.

Referring to FIG. 1, a transport apparatus 100 may transport a transport object 50 to a target location within a semiconductor manufacturing plant. The transport object 50 may be a container such as a Front Opening Unified Pod (FOUP) that houses multiple substrates or a magazine that houses chips, but the present disclosure is not limited thereto. The transport object 50 will hereinafter be described, for example, as a magazine.

The target location may be, for example, a place for a back-end process that evaluates the performance of a product completed through a front-end process, but the present disclosure is not limited thereto. More than one target location may be provided within transport equipment. In a semiconductor manufacturing plant, a transfer path may be provided to pass through the target location.

The transfer path may be set by a traveling rail 70 connected to the ceiling. A loading area for the transport object 50 may be installed below the traveling rail 70. The traveling rail 70 may include straight sections and curved sections.

The transport apparatus 100 may be provided as an Overhead Hoist Transport (OHT). The transport apparatus 100 may travel along the traveling rail 70 to transport the transport object 50 to the target location. For example, the transport apparatus 100 may include a vehicle 110, a housing 130, a transfer module 150, and slide units 170.

The vehicle 110 may be provided with traveling wheels 111 on both sides that are rotated by a motor 113 to travel along the traveling rail 70. The vehicle 110 may travel while the traveling wheels 111 rotate in contact with the traveling rail 70. A steering wheel (not illustrated) may be provided on the upper surface of the vehicle 110. The steering wheel may be configured to move along a front-rear direction 20 perpendicular to a traveling direction 10 of the vehicle 110. For example, the steering wheel may selectively contact a straight steering rail (not illustrated) guiding straight travel and a branch steering rail (not illustrated) guiding branch travel.

The housing 130 may be connected to the vehicle 110 below the traveling rail 70. The housing 130 may have an internal space 130S. The housing 130 may have a structure with its bottom and one or both sides open for vertical and horizontal movement (e.g., the traveling direction 10 and the front-rear direction 20) of the transport object 50. Here, both sides may refer to the traveling direction 10 of the transport apparatus 100 and the front-rear direction 20.

The transfer module 150 may transfer the transport object 50 from the loading area to the internal space 130S or from the internal space 130S to the loading area through the open bottom of the housing 130.

The transfer module 150 may be provided in the housing 130. The transfer module 150 may load and unload the transport object 50. The transfer module 150 may include a horizontal movement unit 151, a lifting unit 153, and a hand unit 155.

The horizontal movement unit 151 may be provided on the inner upper surface of the housing 130. The horizontal movement unit 151 may move horizontally through the open sides of the housing 130. Although not illustrated, for example, the horizontal movement unit 151 may include a guide rail and a moving block or may be equipped with multiple sliding plates.

The lifting unit 153 may be provided below the horizontal movement unit 151 and may be moved horizontally by the horizontal movement unit 151. The lifting unit 153 may raise and lower the hand unit 155. The lifting unit 153 may include a driver (not illustrated) such as a motor and a belt 155B. The belt 155B may move the hand unit 155 in an up-down direction 30 by the driving force of the driver. For example, the driver may generate driving force to wind or unwind the belt 155B, i.e., adjust the length of the belt 155B, to move the hand unit 155 in the up-down direction 30 and adjust the height of the hand unit 155.

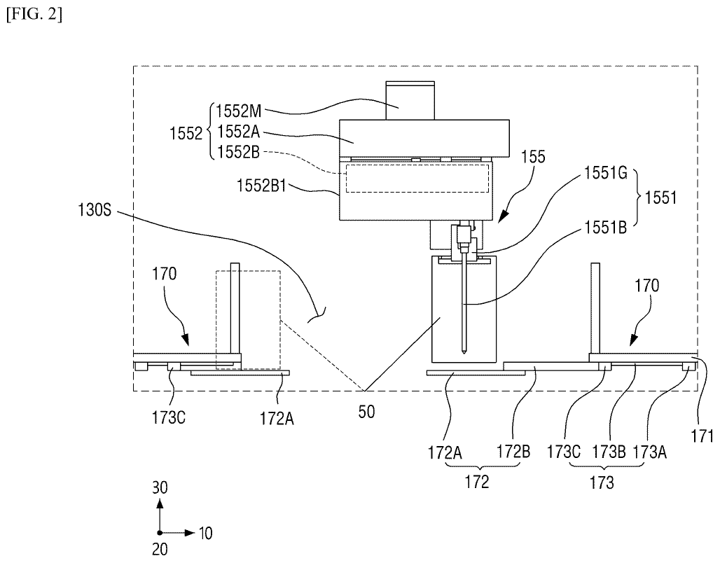

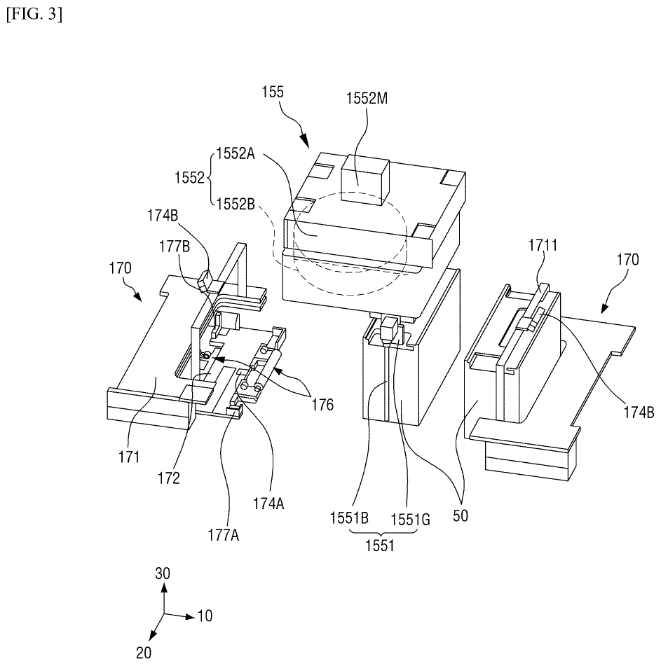

The hand unit 155 may move in the up-down direction 30 in the housing 130 by the lifting unit 153 and may grip or ungrip the transport object 50. For example, the hand unit 155 may be fixed to the end of the belt 155B and connected to the lifting unit 153 through the belt 155B. The hand unit 155 may be provided to rotate, as will be explained later with reference to FIGS. 2 and 3.

The hand unit 155 and the slide units 170 will hereinafter be described with reference to the drawings.

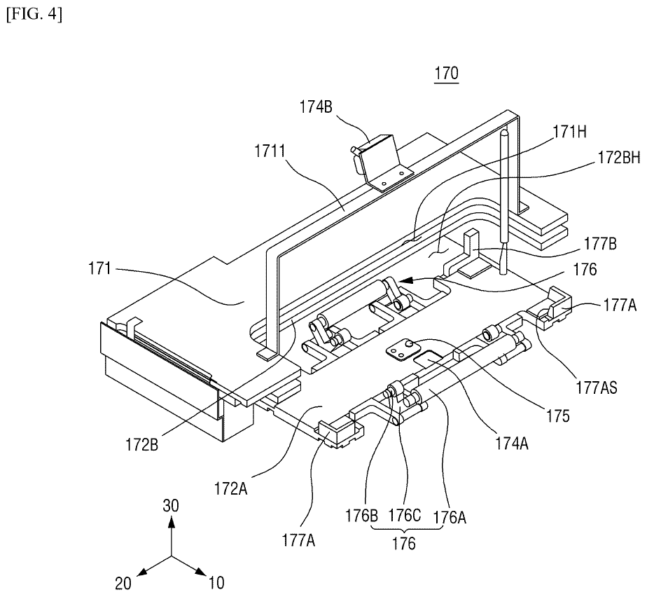

FIG. 2 illustrates the hand unit and the slide unit of the transport apparatus according to some embodiments of the present disclosure, FIG. 3 is a perspective view of a hand unit and a slide unit of a transport apparatus according to a first embodiment of the present disclosure, and FIG. 4 is a perspective view of the slide unit of the transport apparatus according to the first embodiment of the present disclosure.

First, referring to FIGS. 2 and 3, the hand unit 155 may include a chucking module 1551 and a rotation module 1552.

The chucking module 1551 may grip the transport object 50. The chucking module 1551 may include a gripper 1551G and a chip detachment prevention bar 1551B.

The gripper 1551G may be provided in an “L” shape and may slide to fit onto or be separated from the top of the magazine, which is the transport object 50. Although not illustrated in the drawings, the gripper 1551G may move in the longitudinal direction of the transport object 50 (i.e., the front-rear direction 20) by a motor to grip or ungrip the transport object 50.

The chip detachment prevention bar 1551B may be adjacent to the gripper 1551G and may extend across the front and rear of the magazine, which is the transport object 50, to prevent the chips stored in the transport object 50 from being detached. For example, the chip detachment prevention bar 1551B may be provided as a bar or rod extending in the up-down direction 30.

Additionally, the chucking module 1551 may be provided with a sensor (not illustrated) to detect whether the transport object 50 is properly seated.

The rotation module 1552 may rotate the chucking module 1551.

The rotation module 1552 may include a fixed body 1552A, a turntable 1552B, and a second motor 1552M.

The fixed body 1552A may secure the belt 155B and may house the second motor 1552M. For example, the second motor 1552M may be installed on the upper surface of the fixed body 1552A, and the shaft of the second motor 1552M may pass through the fixed body 1552A and may be connected to the turntable 1552B. The second motor 1552M installed on the fixed body 1552A may have its shaft connected to the turntable 1552B and may thus rotate the turntable 1552B.

The turntable 1552B may be provided with a box-shaped body 1552B1 and may rotate relative to the fixed body 1552A, with a rotation angle ranging from 0° to 270°. This prevents excessive rotation (e.g., 360° rotation) of the turntable 1552B, which may cause the wires supplying power to components requiring power, such as motors for operating the chucking module 1551, to twist or break.

In other words, the turntable 1552B may be provided with wires wound therearound to avoid the need for a separate space for the wires and to prevent twisting of the wires, ensuring safe storage by rotating within a range of 0° to 270°, rather than completing a 360° rotation.

Furthermore, even though the turntable 1552B does not complete a 360° rotation, it may return to the 0° position and achieve the 360° position. Therefore, the turntable 1552B may rotate to correspond to all positions of the transport object 50, such as 0 o'clock (or 12 o'clock), 3 o'clock, 6 o'clock, and 9 o'clock.

Referring to FIGS. 2 through 4, the slide units 170 may move horizontally in the direction 10 in which the hand unit 155 is positioned, in the housing 130. A pair of slide units 170 may be provided, facing each other with the hand unit 155 therebetween within the internal space 130S of the housing 130, and may be provided separately from the hand unit 155. That is, the horizontal movement unit 151 may slide to allow the horizontal movement of the hand unit 155, and the slide units 170 may slide to either separate from or approach the hand unit 155 so that the transport object 50 may be seated.

The slide units 170 may have a slidable structure where the transport object 50 gripped by the hand unit 155 may be seated.

For example, each of the slide units 170 may include a base plate 171, a slide plate 172, a drive module 173, a reflector 174A, a first sensor 174B, a contact sensor 175, fall prevention parts 176, a first detachment prevention block 177A, and a second detachment prevention block 177B.

The base plate 171 may be fixed within the internal space of the housing 130. The base plate 171 may have a first cutting hole 171H formed on one side into which the transport object 50 may be inserted. That is, the base plate 171 may have a structure with an open side formed by the first cutting hole 171H to allow the transport object 50 to slide and enter, encompassing the longitudinal direction of the transport object 50 (i.e., the front-rear direction 20) when the slide plate 172, where the transport object 50 is seated, returns.

The base plate 171 may include a first transport object detachment prevention unit 1711. The first transport object detachment prevention unit 1711 may form a band shape surrounding the transport object 50 in the front-rear direction 20 perpendicular to the movement direction of the slide plate 172 (i.e., the traveling direction 10), without interfering with the movement of the slide plate 172. For example, the magazine, which is the transport object 50, may have an opening in the front-rear direction 20 perpendicular to the movement direction of the slide plate 172, exposing the chips. The chips may fall if the magazine shakes or loses balance, thus, to prevent this, the first transport object detachment prevention unit 1711 may be provided.

The slide plate 172 may slide from the base plate 171 in the traveling direction 10, where the hand unit 155 is disposed, and the transport object 50 may be seated on the slide plate 172. For example, the slide plate 172 may include a first plate 172A and a second plate 172B.

The first plate 172A may cover the lower part of the first cutting hole 171H and may seat the transport object 50. The first plate 172A may be equipped with the reflector 174A, the contact sensor 175, and the fall prevention parts 176.

The second plate 172B may be provided between the base plate 171 and the first plate 172A and may have a second cutting hole 172BH corresponding to the first cutting hole 171H. The second plate 172B may slide along with the first plate 172A to extend the protruding length of the first plate 172A.

The drive module 173 may be provided on the base plate 171 and may slide the slide plate 172 so that the slide plate 172 may protrude from the base plate 171. For example, referring to FIG. 2, the drive module 173 may include a moving block 173C, a ball screw 173B, and a first motor 173A.

The moving block 173C may be penetrated by the ball screw 173B and may be fixed to the slide plate 172. The moving block 173C may move in conjunction with the rotation of the ball screw 173B, and the slide plate 172 may slide in conjunction with the movement of the moving block 173C.

The ball screw 173B may be provided in the form of a rod with threads formed on its outer surface, and may convert the rotational force generated by the first motor 173A into linear motion, thereby moving the moving block 173C in the traveling direction 10, where the hand unit 155 is disposed. To achieve this, the ball screw 173B may be connected to the shaft of the first motor 173A, and the moving block 173C may be penetrated.

The first motor 173A may be provided with a shaft and may rotate the ball screw 173B connected to the shaft. When the first motor 173A is driven, the moving block 173C may move due to the rotation of the ball screw 173B driven by the first motor 173A, and the slide plate 172 may slide.

Meanwhile, the first motor 173A is illustrated as being disposed on the lower surface of the base plate 171, but the present disclosure is not limited thereto. For example, the first motor 173A may be provided on the upper surface of the base plate 171, and a drive pulley (not illustrated) and a drive belt (not illustrated) may be further provided in the first motor 173A, and the ball screw 173B may have a structure rotatable by the drive belt and/or the drive pulley.

Additionally, although not illustrated, various modifications may be possible, such as providing linear motor (LM) guiders on the base plate 171, the first plate 172A, and/or the second plate 172B to support the sliding movement of each of the slide units 170.

The reflector 174A may be provided at the location where the transport object 50 is seated on the upper surface of the slide plate 172, and may be provided, for example, as a sticker coated with a reflective material to reflect laser light emitted by the first sensor 174B.

The first sensor 174B may detect the reflector 174A at the first transport object detachment prevention unit 1711. Here, since the reflector 174A is disposed at the location where the transport object 50 is seated, when the transport object 50 is seated on the slide plate 172, the first sensor 174B may detect that the transport object 50 is seated because no laser light is reflected from the reflector 174A.

The contact sensor 175 may be provided on the slide plate 172 and may detect the transport object 50. For example, the contact sensor 175 may be a push sensor that is pressed when the transport object 50 is seated.

A pair of fall prevention parts 176 may be provided on both sides of the transport object 50 on the slide plate 172 to restrict both sides of the transport object 50.

For example, each of the fall prevention parts 176 may include an upper roller 176A, lower rollers 176B, and a rotating body 176C.

The upper roller 176A may have a length in the longitudinal direction of the transport object 50 (i.e., the front-rear direction 20). The lower rollers 176B may be provided below the upper roller 176A, and a pair of lower rollers 176B may be provided. The rotating body 176C may be provided to rotate the upper roller 176A and the lower rollers 176B, and may be provided to pivot on the slide plate 172, having a “V” shape that rotates to allow the upper roller 176A to contact the transport object 50 when the transport object 50 contacts the lower rollers 176B (refer to FIG. 4). The rotating body 176C may be provided with a spring (not illustrated) such that, when the transport object 50 is not seated, the upper roller 176A returns to a position where it does not contact the transport object 50, being elastically supported away from the position where it contacts the transport object 50.

The first detachment prevention block 177A may be provided on the upper surface of the slide plate 172 and may contact the other side of the transport object 50. For example, the first detachment prevention block 177A may have an “L” shape when viewed from above, contacting the corners of the other side of the transport object 50, but the present disclosure is not limited thereto. Additionally, the first detachment prevention block 177A may have an inclined surface 177AS guiding the path where the transport object 50 is seated from top to bottom. The inclined surface 177AS may be provided as a gradually downwardly inclined surface in the direction where the transport object 50 is seated.

The second detachment prevention block 177B may be provided on the upper surface of the slide plate 172, opposite to the first detachment prevention block 177A, and may contact one side of the transport object 50, thereby constraining both sides of the transport object 50 together with the first detachment prevention block 177A.

In the transport apparatus 100, the vehicle 110 may move to the loading area where the transport object 50 is located and may face the transport object 50 in the up-down direction 30.

At this time, the orientation of the transport object 50 may be random, such as 12′clock or 3 o'clock, so the chucking module 1551 of the hand unit 155 needs to rotate to the direction in which the transport object 50 can be gripped. To achieve this, the rotation module 1552 of the hand unit 155 may rotate. Simultaneously or sequentially, the hand unit 155 may descend within the internal space 130S of the housing 130.

Subsequently, the chucking module 1551 may grip the transport object 50, and the hand unit 155 may ascend again to be positioned within the internal space 130S of the housing 130. Then, the rotation module 1552 may rotate corresponding to the slide plate 172 so that the transport object 50 may be seated on the slide unit 170, where the transport object 50 is not seated. That is, the rotation module 1552 may rotate so that the transport object 50 gripped by the chucking module 1551 may be seated on the slide plate 172. Then, the slide plate 172 of the slide unit 170 may slide so that the transport object 50 may be seated on the slide plate 172. Once the transport object 50 is seated on the slide plate 172, the slide plate 172 may return to its original position, and the vehicle 110 may move to its destination location.

Although the embodiments of the present disclosure have been described with reference to the accompanying drawings, those skilled in the art will understand that various modifications can be made without departing from the technical idea or essential features of the present invention. Therefore, the embodiments described above should be considered in all respects as illustrative and not restrictive.

What is claimed is:

1. A transport apparatus comprising:
a vehicle;
a housing connected to the vehicle and forming an internal space with an open bottom;
a hand unit provided to be movable in an up-down direction, in the housing and to grip and upgrip a transport object; and
a slide unit separated from the hand unit, in the housing, and moving horizontally in a direction where the hand unit is disposed,
wherein the slide unit includes: a base plate provided in the internal space of the housing; a slide plate sliding from the base plate in the direction where the hand unit is disposed and seating the transport object; and a drive module provided on the base plate, and sliding the slide plate so that the slide plate protrudes from the base plate.

2. The transport apparatus of claim 1, wherein a pair of slide units are provided, facing each other with the hand unit therebetween within the internal space of the housing.

3. The transport apparatus of claim 1, wherein
the base plate is formed with a first cutting hole into which one side of the transport object is inserted, and
the slide plate includes a first plate covering a lower part of the first cutting hole to seat the transport object.

4. The transport apparatus of claim 3, wherein the slide plate further includes a second plate provided between the base plate and the first plate and formed with a second cutting hole corresponding to the first cutting hole.

5. The transport apparatus of claim 3, wherein the base plate includes a first transport object detachment prevention unit forming a band shape surrounding the transport object in a direction perpendicular to a movement direction of the slide plate without interfering with the movement of the slide plate.

6. The transport apparatus of claim 5, wherein the slide unit further includes: a reflector provided at a position where the transport object is seated on an upper surface of the slide plate; and a first sensor detecting the reflector at the first transport object detachment prevention unit.

7. The transport apparatus of claim 5, wherein the slide unit further includes a contact sensor provided on the slide plate to detect the transport object.

8. The transport apparatus of claim 1, wherein
the drive module includes: a moving block fixed to the slide plate; a ball screw penetrated by the moving block; and a first motor rotating the ball screw, and
as the moving block moves due to the rotation of the ball screw driven by the first motor, the slide plate slides.

9. The transport apparatus of claim 1, wherein
the slide unit includes a pair of fall prevention parts provided on both sides of the transport object on the slide plate, and
each of the fall prevention parts includes: an upper roller having a length in a longitudinal direction of the transport object; a lower roller provided below the upper roller; and a rotating body allowing the upper roller and the lower roller to rotate, provided to pivot on the slide plate, and having a “V” shape that rotates to allow the upper roller to contact the transport object when the transport object contacts the lower roller.

10. The transport apparatus of claim 1, wherein the slide unit further includes a first detachment prevention block provided on an upper surface of the slide plate and contacting one side of the transport object.

11. The transport apparatus of claim 10, wherein the first detachment prevention block is formed with an inclined surface that guides a path where the transport object is seated in a top-to-bottom direction.

12. The transport apparatus of claim 10, wherein the slide unit further includes a second detachment prevention block provided on the upper surface of the slide plate, opposite to the first detachment prevention block, and contacting the other side of the transport object.

13. The transport apparatus of claim 1, wherein the hand unit includes: a chucking module gripping the transport object; and a rotation module rotating the chucking module.

14. The transport apparatus of claim 13, wherein
the transport object is provided as a magazine housing chips, and
the chucking module includes a gripper sliding to fit onto or separate from the top of the magazine.

15. The transport apparatus of claim 14, wherein the chucking module further includes a chip detachment prevention bar adjacent to the gripper, extending across the front and rear of the magazine to prevent the chips housed in the magazine from being detached.

16. The transport apparatus of claim 13, further comprising:
a lifting unit including a belt with adjustable length to raise and lower the hand unit.

17. The transport apparatus of claim 16, wherein the rotation module includes: a fixed body to which the belt is fixed; a turntable rotating relative to the fixed body, with a rotation angle ranging from 0° to 270°; and a second motor provided on the fixed body to rotate the turntable.

18. A transport apparatus comprising:
a vehicle;
a housing connected to the vehicle and forming an internal space with an open bottom;
a hand unit provided to be movable in an up-down direction, in the housing, and to grip and release a transport object, which is provided as a magazine housing chips;
a lifting unit including a belt with adjustable length to raise and lower the hand unit, in the housing; and
a pair of slide units provided facing each other with the hand unit therebetween within the internal space of the housing, and moving horizontally in a direction where the hand unit is disposed,
wherein
the slide unit includes: a base plate provided in the internal space of the housing, formed with a first cutting hole into which one side of the transport object is inserted, and provided with a first transport object detachment prevention unit forming a band shape surrounding the transport object; a slide plate including a first plate covering the lower part of the first cutting hole and seating the transport object, and a second plate provided between the base plate and the first plate, formed with a second cutting hole corresponding to the first cutting hole, and sliding from the base plate in the direction where the hand unit is disposed; a drive module including a moving block fixed to the slide plate, a ball screw penetrated by the moving block, and a first motor provided on the base plate to rotate the ball screw, and causing the slide plate to slide and protrude from the base plate as the moving block moves due to the rotation of the ball screw driven by the first motor; a reflector provided at a position where the transport object is seated on an upper surface of the slide plate; a first sensor provided at the first transport object detachment prevention unit to detect the reflector; a contact sensor provided on the slide plate to detect the transport object; a first detachment prevention block provided on the upper surface of the slide plate, contacting one side of the transport object, and formed with an inclined surface that guides a path where the transport object is seated from top to bottom; a second detachment prevention block provided on the upper surface of the slide plate, opposite to the first detachment prevention block, and contacting the other side of the transport object; and a pair of fall prevention parts provided on both sides of the transport object on the first plate,
each of the fall prevention parts includes: an upper roller having a length in the longitudinal direction of the transport object; a lower roller provided below the upper roller; and a rotating body allowing the upper roller and the lower roller to rotate, provided to pivot on the slide plate and having a “V” shape that rotates to allow the upper roller to contact the transport object when the transport object contacts the lower roller, and
the hand unit further includes: a chucking module gripping the transport object, including a gripper that slides to fit onto or separate from the top of the magazine and a chip detachment prevention bar extending across the front and rear of the magazine to prevent the chips housed in the magazine from being detached; and a rotation module including a fixed body to which the belt is fixed, a turntable rotating relative to the fixed body with a rotation angle ranging from 0° to 270°, and a second motor provided on the fixed body to rotate the turntable.
